(19) United States
(12) Patent Application Publication
(10) Pub. No.: US 2024/0071918 A1
(43) Pub. Date: Feb. 29, 2024

(54) MICROELECTRONIC DEVICES INCLUDING STADIUM STRUCTURES, AND RELATED MEMORY DEVICES AND ELECTRONIC SYSTEMS

(71) Applicant: Micron Technology, Inc., Boise, ID (US)

(72) Inventors: Lifang Xu, Boise, ID (US); Sidhartha Gupta, Boise, ID (US); Indra V. Chary, Boise, ID (US); Richard J. Hill, Boise, ID (US); Umberto Maria Meotto, Dietlikon (CH)

(21) Appl. No.: 17/822,421

(22) Filed: Aug. 25, 2022

(51) Int. Cl. H01L 23/528; H01L 23/535; H01L 27/11556; H01L 27/11582

(52) U.S. Cl. CPC H01L 23/5283; H01L 23/535; H01L 27/11556; H01L 27/11582

(57) ABSTRACT

A microelectronic device includes a stack structure having tiers each including conductive material vertically neighboring insulative material and conductive contact structures. The stack structure is divided into blocks horizontally extending in parallel in a first direction and separated from one another in a second direction orthogonal to the first direction by insulative slot structures. At least one of the blocks includes a lower stadium structure having steps including edges of some of the tiers, and an upper stadium structure vertically overlying the lower stadium structure and having additional steps including edges of some other of the tiers vertically overlying the some of the tiers. The additional steps have greater tread widths in the first direction than the steps. Conductive contact structures are in contact with the additional steps of the upper stadium structure of the at least one of the blocks. Memory devices and electronic systems are also described.

### TECHNICAL FIELD

The disclosure, in various embodiments, relates generally to the field of microelectronic device design and fabrication. More specifically, the disclosure relates to microelectronic devices including stadium structures, and to related memory devices and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often seek to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes strings of memory cells vertically extending through one or more stack structures including tiers of conductive material and insulative structure. Each string of memory cells may include at least one select device coupled thereto. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Vertical memory array architectures generally include electrical connections between the conductive material of the tiers of the stack structure(s) of the memory device and control logic devices (e.g., string drivers) so that the memory cells of the vertical memory array can be uniquely selected for writing, reading, or erasing operations. One method of forming such an electrical connection includes forming so-called “staircase” (or “stair step”) structures at edges (e.g., horizontal ends) of the tiers of the stack structure(s) of the memory device. The staircase structure includes individual “steps” defining contact regions for the conductive material of the tiers, upon which conductive contact structures can be positioned to provide electrical access to the conductive material. In turn, conductive routing structures can be employed to couple the conductive contact structures to the control logic devices. Unfortunately, as feature packing densities have increased and margins for formation errors have decreased, conventional fabrication methods and resulting structural configurations have resulted in undesirable defects that can diminish desired memory device performance, reliability, and durability.

### BRIEF DESCRIPTION OF THE DRAWINGS

FIG. 1 is a simplified, partial perspective view of a microelectronic device structure, in accordance with embodiments of the disclosure.

FIG. 2A is a simplified, partial top-down view of the microelectronic device structure shown in FIG. 1. FIG. 2B is a simplified, longitudinal cross-sectional view of a portion A of the microelectronic device structure shown in FIGS. 1 and 2A. FIG. 2C is a simplified, partial longitudinal cross-sectional view of a portion of the microelectronic device structure of FIG. 2A about a dashed line B-B shown in FIGS. 2A and 2B. FIG. 2D is a simplified, partial longitudinal cross-sectional view of a portion of the microelectronic device structure of FIG. 2A about a dashed line C-C shown in FIGS. 2A and 2B.

FIG. 3 is a simplified, partial top-down view of a microelectronic device structure, in accordance with additional embodiments of the disclosure.

FIG. 4 is a simplified, partial top-down view of a microelectronic device structure, in accordance with further embodiments of the disclosure.

FIG. 5 is a simplified, partial top-down view of a microelectronic device structure, in accordance with yet further embodiments of the disclosure.

FIG. 6 is a simplified partial cutaway perspective view of a microelectronic device, in accordance with embodiments of the disclosure.

FIG. 7 is a schematic block diagram illustrating an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. The description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessary limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pa), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative structure” means and includes electrically insulative structure, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative structure may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative structure.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

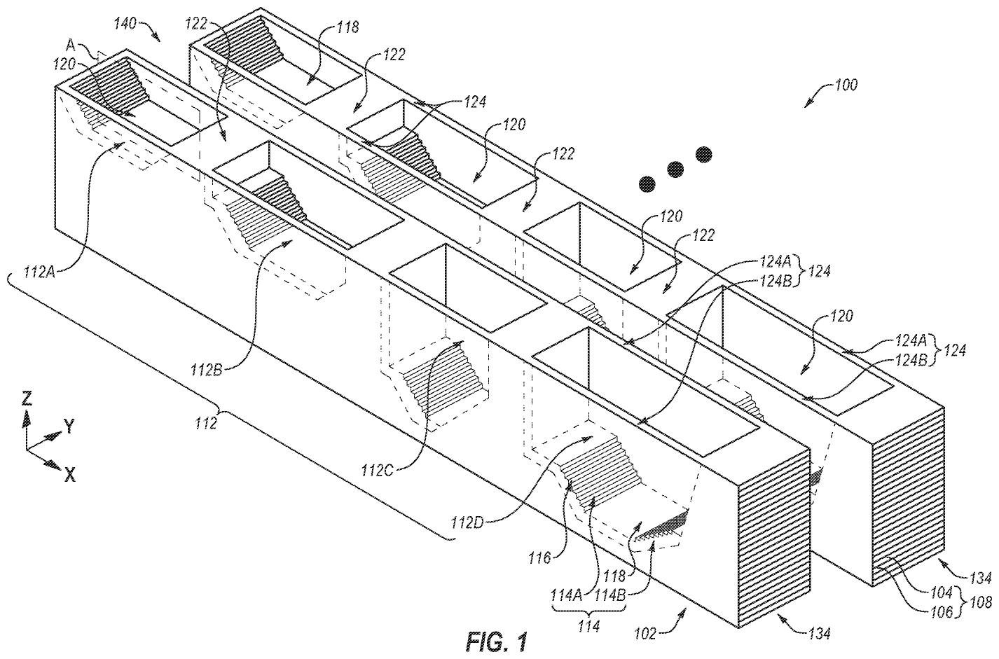

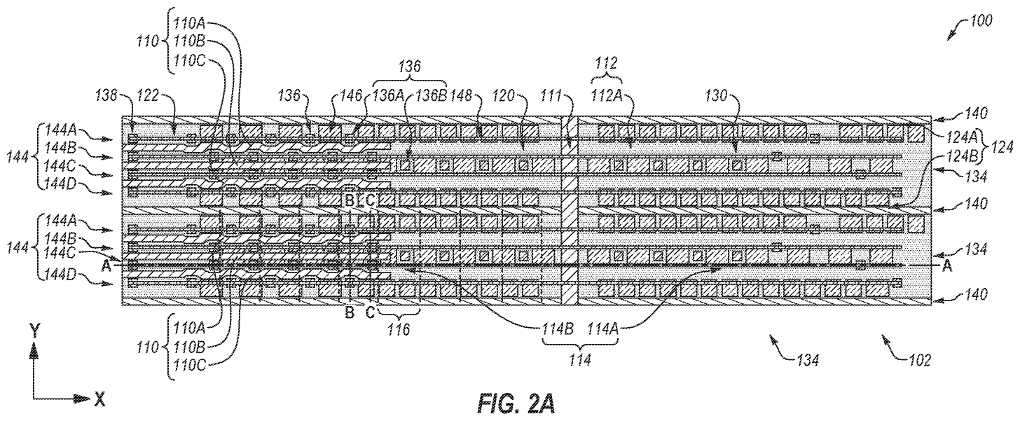

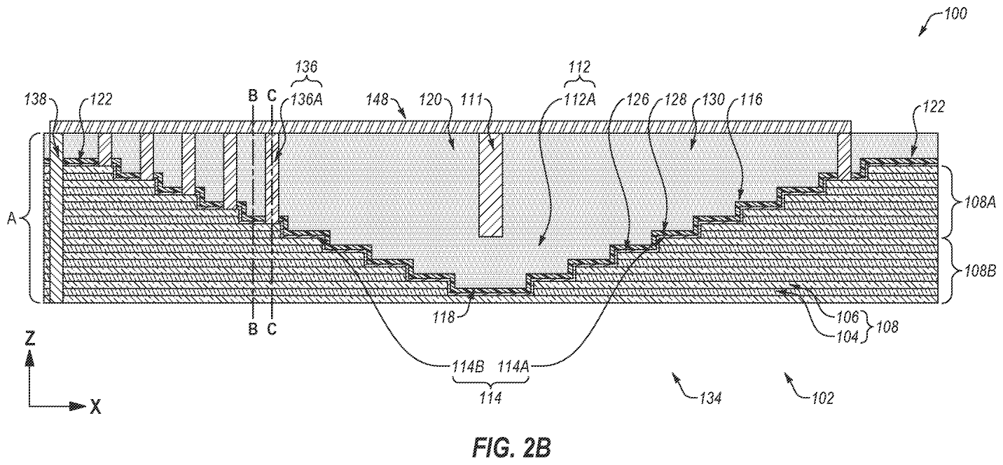

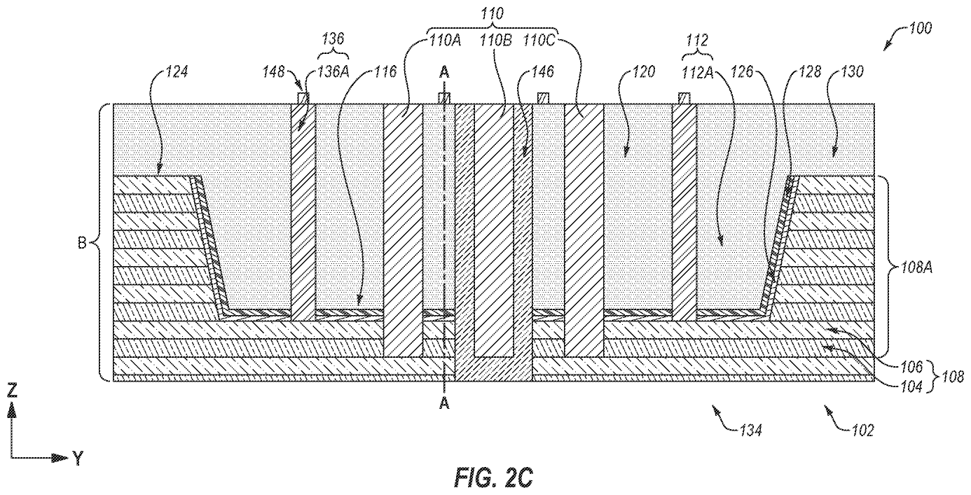

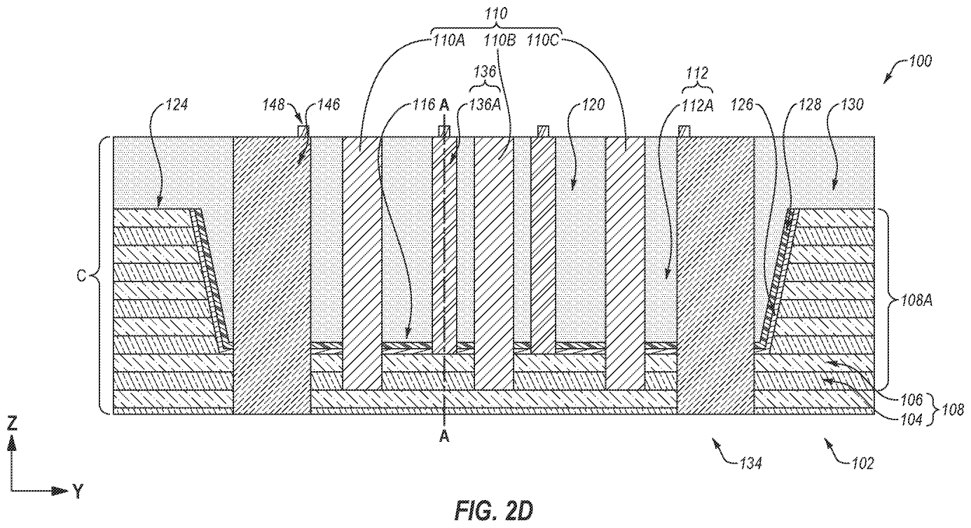

FIGS. 1 and 2A through 2D are various views (described in further detail below) illustrating a microelectronic device structure 100 for a microelectronic device (e.g., a memory device, such as a 3D NAND Flash memory device), in accordance with embodiments of the disclosure. With the description provided below, it will be readily apparent to one of ordinary skill in the art that the structures (e.g., the microelectronic device structure 100) and devices (e.g., microelectronic devices) described herein may be employed in various relatively larger devices and/or systems. For clarity and ease of understanding the drawings and associated description, not all features (e.g., regions, structures, materials, devices) of the microelectronic device structure 100 depicted in one or more of FIGS. 1 and 2A through 2D are depicted in the one or more other of FIGS. 1 and 2A through 2D.

FIG. 1 depicts a simplified, partial perspective view of the microelectronic device structure 100. As shown in FIG. 1, the microelectronic device structure 100 may be formed to include a stack structure 102 including a vertically alternating (e.g., in a Z-direction) sequence of insulative material 104 and conductive material 106 arranged in tiers 108. Each of the tiers 108 of the stack structure 102 may individually include the conductive material 106 vertically neighboring (e.g., directly vertically adjacent) the insulative material 104. Additional features (e.g., materials, structures, regions) of the stack structure 102 are described in further detail below. FIG. 2A is a simplified, longitudinal cross-sectional view of a portion A (identified with a dashed box in FIG. 1) of the microelectronic device structure 100 depicted in FIG. 1. FIG. 2B is a simplified, longitudinal cross-sectional view of the portion A of the microelectronic device structure shown in FIGS. 1 and 2A. FIG. 2C is a simplified, partial longitudinal cross-sectional view of a portion of the microelectronic device structure 100 about a dashed line B-B shown in FIGS. 2A and 2B. FIG. 2D is a simplified, partial longitudinal cross-sectional view of a portion of the microelectronic device structure 100 about a dashed line C-C shown in FIGS. 2A and 2B.

The insulative material 104 of each of the tiers 108 of the stack structure 102 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the insulative material 104 of each of the tiers 108 of the stack structure 102 is formed of and includes a dielectric oxide material, such as SiOₓ (e.g., SiO₂). The insulative material 104 of each of the tiers 108 may be substantially homogeneous, or the insulative material 104 of one or more (e.g., each) of the tiers 108 may be heterogeneous.

The conductive material 106 of each of the tiers 108 of the stack structure 102 may formed of and include one or more of at least one metal, at least one alloy, and at least one conductive metal-containing material (e.g., at last one conductive metal nitride, at least one conductive metal silicide, at least one conductive metal carbide, at least one conductive metal oxide), and least one conductively doped semiconductor material (e.g., conductively doped polysilicon). In some embodiments, the conductive material 106 are formed of and include tungsten (W). Optionally, at least one liner material (e.g., at least one insulative liner material, at least one conductive liner materials) may be formed around the conductive material 106. The liner material may, for example, be formed of and include one or more a metal (e.g., Ti, Ta), an alloy, a metal nitride (e.g., TiN_{y}, TaN_{y}), and a metal oxide (e.g., AlOₓ). In some embodiments, the liner material comprises at least one conductive material employed as a seed material for the formation of the conductive material 106. In some embodiments, the liner material comprises titanium nitride (TiNₓ, such as TiN). In further embodiments, the liner material further includes aluminum oxide (AlOₓ, such as Al₂O₃). As a non-limiting example, for each of the block 134 of the stack structure 102, AlOₓ (e.g., Al₂O₃) may be formed directly adjacent the insulative materials 104, TiNₓ (e.g., TiN) may be formed directly adjacent the AlOₓ, and W may be formed directly adjacent the TiNₓ. For clarity and ease of understanding the description, the liner material is not illustrated, but it will be understood that the liner material may be disposed around the conductive material 106. The conductive material 106 of each of the tiers 108 of the stack structure 102 may be formed through a so-called “replacement gate” process wherein sacrificial material (e.g., dielectric nitride, such as SiN_{y}) of a preliminary stack structure is selectively removed (e.g., using a wet etchant comprising phosphoric acid (H₃PO₄)) relative to insulative material of the insulative materials 104, and then the resulting voids are filled with conductive material to form the conductive material 106.

Optionally, one or more liner materials(s) (e.g., insulative liner material(s), conductive wirer material(s)) may also be formed around the conductive material 106. The liner material(s) may, for example, be formed of and include one or more a metal (e.g., titanium, tantalum), an alloy, a metal nitride (e.g., tungsten nitride, titanium nitride, tantalum nitride), and a metal oxide (e.g., aluminum oxide). In some embodiments, the liner material(s) comprise at least one conductive material employed as a seed material for the formation of the conductive material 106. In some embodiments, the liner material(s) comprise titanium nitride. In further embodiments, the liner material(s) further include aluminum oxide. As a non-limiting example, aluminum oxide may be formed directly adjacent the insulative material 104, titanium nitride may be formed directly adjacent the aluminum oxide, and tungsten may be formed directly adjacent the titanium nitride. For clarity and ease of understanding the description, the liner material(s) are not illustrated in FIG. 1, but it will be understood that the liner material(s) may be disposed around the conductive material 106.

The stack structure 102 may be formed to include any desired quantity of the tiers 108. By way of non-limiting example, the stack structure 102 may be formed to include greater than or equal to sixteen (16) of the tiers 108, such as greater than or equal to thirty-two (32) of the tiers 108, greater than or equal to sixty-four (64) of the tiers 108, greater than or equal to one hundred and twenty-eight (128) of the tiers 108, or greater than or equal to two hundred and fifty-six (256) of the tiers 108.

Referring still to FIG. 1, the stack structure 102 may be divided into blocks 134 separated from one another by filled slot structures 140. The filled slot structures 140 may vertically extend (e.g., in the Z-direction) completely through the stack structure 102. The blocks 134 and the filled slot structures 140 may horizontally extend parallel in an X-direction. As used herein, the term “parallel” means substantially parallel. Horizontally neighboring blocks 134 of the stack structure 102 may be separated from one another in a Y-direction orthogonal to the X-direction by the filled slot structures 140.

Each of the blocks 134 of the stack structure 102 may exhibit substantially the same geometric configuration (e.g., substantially the same dimensions and substantially the same shape) as each other of the blocks 134, or one or more of the blocks 134 may exhibit a different geometric configuration (e.g., one or more different dimensions and/or a different shape) than one or more other of the blocks 134. In addition, each pair of horizontally neighboring blocks 134 of the stack structure 102 may be horizontally separated from one another by substantially the same distance (e.g., corresponding to a width in the Y-direction of each of the filled slot structures 140) as each other pair of horizontally neighboring blocks 134 of the stack structure 102, or at least one pair of horizontally neighboring blocks 134 of the stack structure 102 may be horizontally separated from one another by a different distance than that separating at least one other pair of horizontally neighboring blocks 134 of the stack structure 102. In some embodiments, the blocks 134 of the stack structure 102 are substantially uniformly (e.g., substantially non-variably, substantially equally, substantially consistently) sized, shaped, and spaced relative to one another.

The filled slot structures 140 may be formed of and include insulative material. The insulative material may include at least one dielectric material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbO₋ₓ₋, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the filled slot structures 140 are formed of and include dielectric oxide material, such as SiOₓ (e.g., SiO₂).

As shown in FIG. 1, the stack structure 102 may include stadium structures 112 formed therein. The stadium structures 112 may be distributed throughout the stack structure 102. As shown in FIG. 1, the stack structure 102 may include rows of the stadium structures 112 extending in parallel in an X-direction, and columns of the stadium structures 112 extending in a Y-direction orthogonal to the X-direction. The rows of the stadium structures 112 may individually include some of the stadium structures 112 at least partially (e.g., substantially) aligned with one another in the Y-direction. The columns of the of the stadium structures 112 may individually include other of the stadium structures 112 at least partially (e.g., substantially) aligned with one another in the X-direction. Different rows of the stadium structures 112 may be positioned within horizontal areas of different blocks 134 of the stack structure 102 than one another. In addition, the columns of the stadium structures 112 may individually include stadium structures 112 within different blocks 134 of the stack structure 102 than one another. In FIG. 1, for clarity and ease of understanding the drawings and associated description, portions of the stack structure 102 are depicted as transparent to more clearly show some of the stadium structures 112 distributed within the stack structure 102.

Still referring to FIG. 1, at least some (e.g., each) of the stadium structures 112 within an individual row of the stadium structures 112 within an individual block 134 may be positioned at different vertical elevations in the Z-direction than one another. For example, an individual row of the stadium structures 112 may include a first stadium structure 112A, a second stadium structure 112B at a relatively lower vertical position (e.g., in the Z-direction) within the stack structure 102 than the first stadium structure 112A, a third stadium structure 112C at a relatively lower vertical position within the stack structure 102 than the second stadium structure 112B, and a fourth stadium structure 112D at a relatively lower vertical position within the block 134 than the third stadium structure 112C. In addition, within an individual row of the stadium structures 112, horizontally neighboring (e.g., in the X-direction) stadium structures 112 may be substantially uniformly (e.g., equally, evenly) horizontally spaced apart from one another. In additional embodiments, one or more rows of the stadium structures 112 may individually include a different quantity of stadium structures 112 and/or a different distribution of stadium structures 112 than that depicted in FIG. 1. For example, an individual row of the stadium structures 112 may include greater than four (4) of the stadium structures 112 (e.g., greater than or equal to five (5) of the stadium structures 112, greater than or equal to ten (10) of the stadium structures 112, greater than or equal to twenty-five (25) of the stadium structures 112, greater than or equal to fifty (50) of stadium structures 112), or less than four (4) of the stadium structures 112 (e.g., less than or equal to three (3) of the stadium structures 112, less than or equal to two (2) of the stadium structures 112, only one (1) of the stadium structures 112). As another example, within an individual row of the stadium structures 112, at least some horizontally neighboring stadium structures 112 may be at least partially non-uniformly (e.g., non-equally, non-evenly) horizontally spaced, such that at least one of the stadium structures 112 of the row is separated from at least two other of the stadium structures 112 of the row horizontally neighboring the at least one stadium structures 112 by different (e.g., non-equal) distances. As an additional non-limiting example, within an individual row of the stadium structures 112, vertical positions (e.g., in the Z-direction) of the stadium structures 112 may vary in a different manner (e.g., may alternate between relatively deeper and relatively shallower vertical positions) than that depicted in FIG. 1.

An individual stadium structure 112 may include opposing staircase structures 114, and a central region 118 horizontally interposed between (e.g., in the X-direction) the opposing staircase structures 114. The opposing staircase structures 114 of an individual stadium structure 112 may include a forward staircase structure 114A and a reverse staircase structure 114B. A phantom line extending from a top of the forward staircase structure 114A to a bottom of the forward staircase structure 114A may have a positive slope, and another phantom line extending from a top of the reverse staircase structure 114B to a bottom of the reverse staircase structure 114B may have a negative slope. In additional embodiments, one or more of the stadium structure 112 may individually exhibit a different configuration than that depicted in FIG. 1. As a non-limiting example, at least one stadium structure 112 may be modified to include a forward staircase structure 114A but not a reverse staircase structure 114B (e.g., the reverse staircase structure 114B may be absent), or at least one stadium structure 112 may be modified to include a reverse staircase structure 114B but not a forward staircase structure 114A (e.g., the forward staircase structure 114A may be absent). In such embodiments, the central region 118 horizontally neighbors a bottom of the forward staircase structure 114A (e.g., if the reverse staircase structure 114B is absent), or horizontally neighbors a bottom of the reverse staircase structure 114B (e.g., if the forward staircase structure 114A is absent).

The opposing staircase structures 114 (e.g., the forward staircase structure 114A and the reverse staircase structure 114B) of an individual stadium structure 112 each include steps 116 defined by edges (e.g., horizontal ends) of the tiers 108 of the stack structure 102. For the opposing staircase structures 114 of an individual stadium structure 112, each step 116 of the forward staircase structure 114A may have a counterpart step 116 within the reverse staircase structure 114B having substantially the same geometric configuration (e.g., shape, dimensions), vertical position (e.g., in the Z-direction), and horizontal distance (e.g., in the X-direction) from a horizontal center (e.g., in the X-direction) of the central region 118 of the stadium structure 112. In additional embodiments, at least one step 116 of the forward staircase structure 114A does not have a counterpart step 116 within the reverse staircase structure 114B having substantially the same geometric configuration (e.g., shape, dimensions), vertical position (e.g., in the Z-direction), and/or horizontal distance (e.g., in the X-direction) from horizontal center (e.g., in the X-direction) of the central region 118 of the stadium structure 112; and/or at least one step 116 of the reverse staircase structure 114B does not have a counterpart step 116 within the forward staircase structure 114A having substantially the same geometric configuration (e.g., shape, dimensions), vertical position (e.g., in the Z-direction), and/or horizontal distance (e.g., in the X-direction) from horizontal center (e.g., in the X-direction) of the central region 118 of the stadium structure 112.

Each of the stadium structures 112 of the stack structure 102 may individually include a desired quantity of steps 116. Each of the stadium structures 112 may include substantially the same quantity of steps 116 as each other of the stadium structures 112, or at least one of the stadium structures 112 may include a different quantity of steps 116 than at least one other of the stadium structures 112. In some embodiments, at least one of the stadium structures 112 includes a different (e.g., greater, lower) quantity of steps 116 than at least one other of the stadium structures 112. As shown in FIG. 1, in some embodiments, the steps 116 of each of the stadium structures 112 are arranged in order, such that steps 116 directly horizontally adjacent (e.g., in the X-direction) one another correspond to tiers 108 of the stack structure 102 directly vertically adjacent (e.g., in the Z-direction) one another. In additional embodiments, the steps 116 of at least one of the stadium structures 112 are arranged out of order, such that at least some steps 116 of the stadium structure 112 directly horizontally adjacent (e.g., in the X-direction) one another correspond to tiers 108 of stack structure 102 not directly vertically adjacent (e.g., in the Z-direction) one another. In some embodiments, an individual stadium structure 112 may be horizontally continuous (e.g., in the Y-direction) such that there is no horizontal region (e.g., in the Y-direction) separating stadium structures 112.

With continued reference to FIG. 1, for an individual stadium structure 112, the central region 118 thereof may horizontally intervene (e.g., in the X-direction) between and separate the forward staircase structure 114A thereof from the reverse staircase structure 114B thereof. The central region 118 may horizontally neighbor a vertically lowermost step 116 of the forward staircase structure 114A, and may also horizontally neighbor a vertically lowermost step 116 of the reverse staircase structure 114B. The central region 118 of an individual stadium structure 112 may have any desired horizontal dimensions. In addition, within an individual stack structure 102, the central region 118 of each of the stadium structures 112 may have substantially the same horizontal dimensions as the central region 118 of each other of the stadium structures 112, or the central region 118 of at least one of the stadium structures 112 may have different horizontal dimensions than the central region 118 of at least one other of the stadium structures 112.

Still referring to FIG. 1, each stadium structure 112 (including the forward staircase structure 114A, the reverse staircase structure 114B, and the central region 118 thereof) within an individual block 134 of the stack structure 102 may individually partially define boundaries (e.g., horizontal boundaries, vertical boundaries) of a filled trench 120 vertically extending (e.g., in the Z-direction) through the stack structure 102. The portions of the stack structure 102 horizontally neighboring an individual stadium structure 112 may also partially define the boundaries of the filled trench 120 associated with the stadium structure 112. The filled trench 120 may only vertically extend through tiers 108 of the stack structure 102 defining the forward staircase structure 114A and the reverse staircase structure 114B of the stadium structure 112; or may also vertically extend through additional tiers 108 of the stack structure 102 not defining the forward staircase structure 114A and the reverse staircase structure 114B of the stadium structure 112, such as additional tiers 108 of the stack structure 102 vertically overlying the stadium structure 112. Edges of the additional tiers 108 of the stack structure 102 may, for example, define one or more additional stadium structures vertically overlying and horizontally offset from the stadium structure 112.

Referring to FIG. 2B, the filled trenches 120 may individually include multiple (e.g., more than one) dielectric materials. For example, each filled trench 120 may include a first dielectric material 126 (e.g., a dielectric liner material), a second dielectric material 128 (e.g., an additional dielectric liner material), and a third dielectric material 130 (e.g., a dielectric fill material). For an individual filled trench 120, the first dielectric material 126 may be formed on or over surfaces (e.g., horizontally extending surfaces, vertically extending surfaces) of the stadium structure 112 (e.g., the first stadium structure 112A) and regions of the stack structure 102 horizontally neighboring and partially defining boundaries (e.g., horizontal boundaries, vertical boundaries) of the filled trench 120; the second dielectric material 128 may be formed on or over the first dielectric material 126; and the third dielectric material 130 may be formed on or over the second dielectric material 128. One or more (e.g., each) of the first dielectric material 126, the second dielectric material 128, and the third dielectric material 130 may also be formed to extend beyond boundaries (e.g., horizontal boundaries, vertical boundaries) of the filled trenches 120. For example, first dielectric material 126, the second dielectric material 128, and the third dielectric material 130 may also be formed to extend over uppermost surfaces of the regions of the stack structure 102 (FIG. 1) horizontally neighboring the filled trenches 120. In some embodiments, the first dielectric material 126 is formed of and includes SiOₓ (e.g., SiO₂), the second dielectric material 128 is formed of and includes SiN_{y} (e.g., Si₂N₄), and the third dielectric material 130 is formed of and includes additional SiOₓ (e.g., additional SiO₂).

With returned reference to FIG. 1, individual blocks 134 of the stack structure 102 may further include crest regions 122 (e.g., elevated regions) and bridge regions 124 (e.g., additional elevated regions). The crest regions 122 may be horizontally alternate with the stadium structures 112 in the X-direction. The bridge regions 124 may horizontally neighbor opposing sides of individual stadium structures 112 in the Y-direction, and may horizontally extend from and between crest regions 122 horizontally neighboring one another in the X-direction.

The crest regions 122 of an individual block 134 of the stack structure 102 may intervene between and separate stadium structures 112 horizontally neighboring one another in the X-direction. For example, one of the crest regions 122 may intervene between and separate the first stadium structure 112A and the second stadium structure 112B; an additional one of the crest regions 122 may intervene between and separate the second stadium structure 112B and the third stadium structure 112C; and a further one of the crest regions 122 may intervene between and separate the third stadium structure 112C and the fourth stadium structure 112D. A vertical height of the crest regions 122 in the Z-direction may be substantially equal to a maximum vertical height of the block 134 in the Z-direction; and a horizontal width of the crest regions 122 in the Y-direction may be substantially equal to a maximum horizontal width of the block 134 in the Y-direction. In addition, each of the crest regions 122 may individually exhibit a desired horizontal length in the X-direction. Each of the crest regions 122 of an individual block 134 of the stack structure 102 may exhibit substantially the same horizontal length in the X-direction as each other of the crest regions 122 of the block 134; or at least one of the crest regions 122 of the block 134 may exhibit a different horizontal length in the X-direction than at least one other of the crest regions 122 of the block 134.

The bridge regions 124 of an individual block 134 of the stack structure 102 may intervene between and separate the stadium structures 112 of the block 134 from the filled slot structures 140 horizontally neighboring the block 134 in the Y-direction. For example, for each stadium structure 112 within an individual block 134 of the stack structure 102, a first bridge region 124A may be horizontally interposed in the Y-direction between a first side of the stadium structure 112 and a first of the filled slot structures 140 horizontally neighboring the block 134; and a second bridge region 124B may be horizontally interposed in the Y-direction between a second side of the stadium structure 112 and a second of the filled slot structures 140 horizontally neighboring the block 134. The first bridge region 124A and the second bridge region 124B may horizontally extend in parallel in the X-direction. In addition, the first bridge region 124A and the second bridge region 124B may each horizontally extend from and between crest regions 122 of the block 134 horizontally neighboring one another in the X-direction. The bridge regions 124 of the block 134 may be integral and continuous with the crest regions 122 of the block 134. Upper boundaries (e.g., upper surfaces) of the bridge regions 124 may be substantially coplanar with upper boundaries of the crest regions 122. A vertical height of the bridge regions 124 in the Z-direction may be substantially equal to a maximum vertical height of the block 134 in the Z-direction. In addition, each of the bridge regions 124 (including each first bridge region 124A and each second bridge region 124B) may individually exhibit a desired horizontal width in the Y-direction and a desired horizontal length in the X-direction. Each of the bridge regions 124 of the block 134 may exhibit substantially the same horizontal length in the X-direction as each other of the bridge regions 124 of the block 134; or at least one of the bridge regions 124 of the block 134 may exhibit a different horizontal length in the X-direction than at least one other of the bridge regions 124 of the block 134. In addition, each of the bridge regions 124 of the block 134 may exhibit substantially the same horizontal width in the Y-direction as each other of the bridge regions 124 of the block 134; or at least one of the bridge regions 124 of the block 134 may exhibit a different horizontal width in the Y-direction than at least one other of the bridge regions 124 of the block 134.

Referring to FIGS. 2C and 2D, inner horizontal boundaries (e.g., inner sidewalls) of each of the bridge regions 124 (e.g., each of the first bridge regions 124A, each of the second bridge regions 124B) of an individual block 134 of the stack structure 102 may be oriented substantially non-perpendicular to uppermost vertical boundaries (e.g., uppermost surfaces) of the block 134. For example, the inner horizontal boundaries of the first bridge regions 124A of an individual block 134 may exhibit negative slope, and the inner horizontal boundaries of the second bridge regions 124B of the block 134 may exhibit positive slope. Horizontal widths in the Y-direction of each bridge region 124 (e.g., a first bridge region 124A and a second bridge region 124B) of a pair of bridge regions 124 horizontally neighboring an individual stadium structure 112 (e.g., a first stadium structure 112A) of the block 134 in the Y-direction may increase in the downward Z-direction (e.g., negative Z-direction) from an uppermost vertical boundary of the stadium structure 112 to a lowermost vertical boundary of the stadium structure 112. Accordingly, relatively vertically lower steps 116 of the stadium structure 112 may have relatively smaller (e.g., narrower) horizontal widths in the Y-direction than relatively vertically higher steps 116 of the stadium structure 112.

As previously described, FIGS. 2A and 2B depict a simplified, partial top-down view (FIG. 2A) and a simplified, longitudinal cross-sectional view (FIG. 2B) of a portion A of the microelectronic device structure 100 shown in FIG. 1. The portion A encompasses the first stadium structure 112A of an individual block 134 of the stack structure 102, along with one of the filled trenches 120 having boundaries defined by the first stadium structure 112A, and additional portions of block 134 horizontally neighboring the first stadium structure 112A. While additional features (e.g., structures, materials) of the microelectronic device structure 100 are described herein below with reference to the portion A of the microelectronic device structure 100, such additional features may also be formed and included in additional portions of the microelectronic device structure 100, including additional portions encompassing additional stadium structures 112 of the stack structure 102 (FIG. 1), additional filled trenches 120 having boundaries defined by the additional stadium structures 112, and additional sections of the stack structure 102 horizontally neighboring the additional stadium structures 112.

Referring to collective to FIGS. 1 and 2A through 2D, for individual block 134, at least some of the steps 116 of the first stadium structure 112A thereof may have greater (e.g., larger) tread dimensions (e.g., widths), in the X-direction, than the steps 116 of relatively vertically lower stadium structures 112 (e.g., the second stadium structure 112B, the third stadium structure 112C, the fourth stadium structure 112D) of the block 134. The tread widths of the steps 116 of the first stadium structure 112A may be greater than conventional tread widths of conventional steps of conventional stadiums structures of conventional microelectronic devices (e.g., conventional 3D NAND memory devices). The relatively greater tread widths of the steps 116 of the first stadium structure 112A may facilitate desirable arrangements of structures (e.g., conductive structures, such as conductive contact structures) on or over the steps 116, as described in further detail below. In some embodiments, the tread widths, in the X-direction, of at least some (e.g., each) of the steps 116 of an individual first stadium structure 112A facilitate multiple structures (e.g., multiple conductive structures, such as multiple conductive contact structures) to be located within the horizontal area of an individual step 116, wherein at least some of the multiple structures are horizontally offset from one another in each of the X-direction and the Y-direction. For example, at least some (e.g., each) the steps 116 may individually be designed to have a tread width, in the X-direction, facilitating desirable spacing, in each of the X-direction and the Y-direction, between horizontally neighboring contacts structures within a horizontal area of an individual step 116. The relatively greater tread widths of the steps 116 of the first stadium structure 112A may alleviate the risk of undesirable electrical shorting between horizontally neighboring contact structures. In some embodiments, at least some (e.g., each) of the steps 116 of an individual first stadium structure 112A have a tread width, in the X-direction, within a range of from about 1200 nanometers (nm) to about 1800 nm.

Referring collectively to FIGS. 2B through 2D, within a horizontal area of the first stadium structure 112A of an individual block 134 of the stack structure 102, contact structures 136 vertically extend (e.g., in the Z-direction) to at least some of the steps 116 of the first stadium structure 112A (e.g., steps 116 of the reverse staircase structure 114B thereof, steps 116 of the forward staircase structure 114A thereof). The contact structures 136 may vertically extend through the filled trench 120 (including the third dielectric material 130, the second dielectric material 128, and the first dielectric material 126 thereof) overlying the first stadium structure 112A. A lower vertical boundary (e.g., a lower surface) of an individual contact structure 136 may physically contact (e.g., land on) the conductive material 106 of an individual tier 108 of the stack structure 102 at an individual step 116 of an individual stadium structure 112. In addition, an upper vertical boundary (e.g., an upper surface) of an individual contact structure 136 substantially coplanar with an upper vertical boundary (e.g., an upper surface) of an individual filled trench (e.g., an upper vertical boundary of the third dielectric material 130 thereof).

As shown in FIG. 2A, the contact structures 136 may include first contact structures 136A and second contact structures 136B. Within a horizontal area of the first stadium structure 112A of an individual block 134 of the stack structure 102, the first contact structures 136A may vertically extend to and terminate at the relatively vertically higher tier(s) 108A of the stack structure 102 (FIGS. 2B through 2D), and the second contact structures 136B may vertically extend to and terminate at the relatively vertically lower tiers 108B of the stack structure 102.

For an individual block 134, multiple (e.g., more than one) first contact structures 136A may vertically extend to portions of an individual vertically higher tier 108A at a step 116 of the first stadium structure 112A. In FIG. 2A dashed lines are illustrated to depict the dimensions and arrangement of some of the steps 116 of the first stadium structure 112A. As shown in FIG. 2A, an individual step 116 of the first stadium structure 112A defined by a horizontal end of an individual vertically higher tier 108A may include multiple first contact structures 136A within a horizontal area thereof. Each first contact structure 136A of a group of the first contact structures 136A within a horizontal area of an individual step 116 of the first stadium structure 112A may be positioned within different sub-blocks 144 of the block 134 than one another. At least some of the first contact structures 136A of the group within the horizontal area of the individual step 116 may be horizontally offset from one another in the X-direction, as described in further detail below. In addition, at least some first contact structures 136A of another group of the first contact structures 136A within a horizontal area of an individual sub-block 144 of the block 134 may be horizontally aligned with one another in the Y-direction, as also described in further detail below.

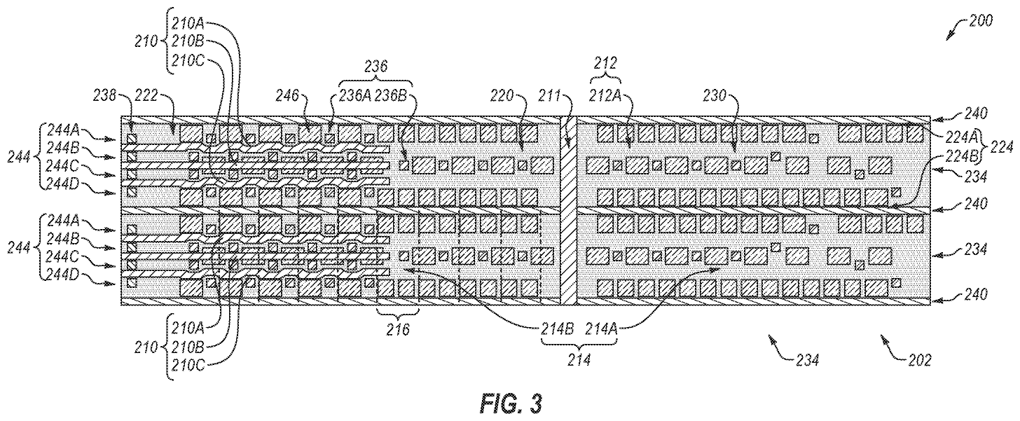

By way of example, an individual group of the first contact structures 136A positioned along (e.g., with a horizontal area of, horizontally overlapping) an individual step 116 of the first stadium structure 112A (e.g., of the reverse staircase structure 114B thereof) defined by an individual vertically higher tier 108A may include four (4) of the first contact structures 136A. An outermost two (2) of the four (4) of the first contact structures 136A of the group in the Y-direction may be substantially aligned with one another in the X-direction. Each of the outermost two (2) of the first contact structures 136A of the group may individually be horizontally proximate one (1) of the filled slot structures 140 in the Y-direction. In addition, an innermost two (2) of the four (4) of the first contact structures 136A of the group in the Y-direction may be substantially aligned with one another in the X-direction. The innermost two (2) of the four (4) of the first contact structures 136A may be offset, in the X-direction, from the outermost two (2) of the four (4) of the first contact structures 136A. As shown in FIG. 2A, the innermost two (2) of the four (4) of the first contact structures 136A may individually be horizontally positioned relatively closer, in the X-direction, to a vertically lower step 116 of the first stadium structure 112A (e.g., of the reverse staircase structure 114B thereof) than the outermost two (2) of the four (4) of the first contact structures 136A. Put another way, the outermost two (2) of the four (4) of the first contact structures 136A may individually be horizontally positioned relatively closer, in the X-direction, to a vertically higher step 116 of the first stadium structure 112A (e.g., of the reverse staircase structure 114B thereof) than the innermost two (2) of the four (4) of the first contact structures 136A. In additional embodiments, the first contact structures 136A of an individual group positioned along an individual step 116 may be arranged differently relative to one another, as described in further detail below with reference to FIGS. 3, 4, and 5.

Still referring to FIG. 2A, within a horizontal area of the first stadium structure 112A of an individual block 134 of the stack structure 102, the second contact structures 136B may vertically extend to and physically contact local access line structures (e.g., word line contacts) of the block 134 formed by portions of the conductive material 106 of the relatively vertically lower tiers 108B of the stack structure 102. A single (e.g., only one) second contact structure 136B may vertically extend to portions of an individual vertically lower tier 108B at a step 116 of the first stadium structure 112A; or multiple (e.g., more than one) second contact structures 136B may vertically extend to portions of an individual vertically lower tier 108B at the step 116 of the first stadium structure 112A. As shown in FIG. 2A, in some embodiments, an individual step 116 of the first stadium structure 112A defined by a horizontal end of an individual vertically lower tier 108B includes only one second contact structure 136B within a horizontal area thereof. In additional embodiments, an individual step 116 of the first stadium structure 112A defined by a horizontal end of an individual vertically lower tier 108B includes at least two (2) second contact structures 136B within a horizontal area thereof.

In some embodiments, within a horizontal area of the first stadium structure 112A of an individual block 134 of the stack structure 102, each of the second contact structures 136B is horizontally centered in at least the Y-direction on a step 116 of the first stadium structure 112A. For example, a horizontal center in the Y-direction of an individual second contact structure 136B may be substantially aligned with a horizontal center in the Y-direction of the step 116 of the first stadium structure 112A that the second contact structure 136B physically contacts (e.g., lands on). In addition, a horizontal center in the X-direction of an individual second contact structure 136B may be substantially aligned with a horizontal center in the X-direction of the step 116 of the first stadium structure 112A that the second contact structure 136B physically contacts. In additional embodiments, one or more of the second contact structures 136B are horizontally offset in the Y-direction from a horizontal center in the Y-direction of the step 116 of the first stadium structure 112A in physical contact therewith, and/or are horizontally offset in the X-direction from a horizontal center in the X-direction of the step 116 of the first stadium structure 112A in physical contact therewith. Second contact structures 136B associated with (e.g., landing on) different steps 116 of the first stadium structure 112A may all be substantially aligned with one another in the Y-direction; or at least one of the second contact structures 136B associated with at least one of the steps 116 of the first stadium structure 112A may be horizontally offset, in the Y-direction, from at least one other of the second contact structures 136B associated with at least one other of the steps 116 of the first stadium structure 112A.

The contact structures 136, including the first contact structures 136A and the second contact structures 136B, may individually be formed of and include conductive material. As a non-limiting example, the contact structures 136 may individually be formed of and include one or more of at least one metal, at least one alloy, and at least one conductive metal-containing material (e.g., a conductive metal nitride, a conductive metal silicide, a conductive metal carbide, a conductive metal oxide). A material composition of the contact structures 136 may be substantially the same as a material composition of the conductive material 106 of the tiers 108 of the stack structure 102, or the material composition of the contact structures 136 may be different than the material composition of the conductive material 106 of the tiers 108 of the stack structure 102. In some embodiments, the contact structures 136 are individually formed of and include W. The contact structures 136 may individually be homogeneous, or the contact structures 136 may individually be heterogeneous.

Referring collectively to FIGS. 2A, 2C and 2D, support structures 146 (e.g., additional contact structures) may be formed to vertically extend (e.g., in the Z-direction) through the filled trenches 120 (including the third dielectric material 130, the second dielectric material 128, and the first dielectric material 126 thereof) and through portions of the stack structure 102 vertically underlying and within horizontal areas of the filled trenches 120. The blocks 134 of the stack structure 102 may individually include some of the support structures 146 within a horizontal area thereof. Configurations and arrangements of the support structures 146 may be selected to mitigate (e.g., prevent) undesirable tier damage (e.g., tier collapse) during so-called “replacement gate” processes to form the conductive material 106 of the tiers 108 of the stack structure 102.

As shown in FIG. 2A, within a horizontal area of the first stadium structure 112A of an individual block 134 of the stack structure 102, at least one array of the support structures 146 may be formed. The array of the support structures 146 may include rows of the support structures 146 extending in the X-direction, and columns of the support structures 146 extending in the Y-direction. The array of the support structures 146 may, for example, include at least two (2) rows (e.g., at least three (3) rows) of the support structures 146 extending in parallel the X-direction. In some embodiments, the array of the support structures 146 includes at least three (3) rows of the support structures 146. The support structures 146 of a row of the support structures 146 may be horizontally offset in the X-direction from the support structures 146 of an additional row of the support structures 146 horizontally neighboring the row of the support structures 146 in the Y-direction. The support structures 146 within in each of the rows of the support structures 146 may individually have substantially the same configuration (e.g., shape, dimensions) and arrangement as each of the support structures 146 within each other of the rows of the support structures 146; or at least one the support structures 146 within at least one of the rows of the support structures 146 may have one or more of a different configuration (e.g., a different shape, at least one different dimension) and a different arrangement than at least one of the support structures 146 within at least one other of the rows of the support structures 146. In addition, a group of the support structures 146 of the array within horizontal areas of steps 116 of the first stadium structure 112A defined by the vertically higher tiers 108A may have a different arrangement than an additional group of the support structures 146 of the array within horizontal areas of steps 116 of the first stadium structure 112A defined by the vertically lower tiers 108B. Furthermore, a group of the support structures 146 within a horizontal area of the forward staircase structure 114A of the first stadium structure 112A may have a different that another group of the support structures 146 within a horizontal area of the reverse staircase structure 114B of the first stadium structure 112A.

Within a horizontal area of the first stadium structure 112A of an individual block 134 of the stack structure 102, an arrangement of the support structures 146 may at least partially depend on an arrangement of the contact structures 136. As shown in FIG. 2A, rows of the support structures 146 may horizontally overlap rows of the first contact structures 136A in the Y-direction, and the support structures 146 of an individual row of the support structures 146 may horizontally alternate, in the X-direction, with the first contact structures 136A of a horizontally overlapping row of the first contact structures 136A. Horizontal centers of the support structures 146 of an individual row of the support structures 146 may be horizontally offset, in the Y-direction, from horizontal centers of the first contact structures 136A of a horizontally overlapping row of the first contact structures 136A. As shown in FIG. 2A, in some embodiments, a single, central row of the support structures 146 partially horizontally overlaps two inner rows of the first contact structures 136A in the Y-direction; and two outer rows of the support structures 146 partially horizontally overlap two outer rows of the first contact structures 136A in the Y-direction. In addition, at least one of the rows of the support structures 146 may horizontally overlap at least one row of the second contact structures 136B in the Y-direction, and the support structures 146 of the at least one row of the support structures 146 may horizontally alternate, in the X-direction, with the second contact structures 136B of a horizontally overlapping row of the second contact structures 136B. Horizontal centers of the support structures 146 of an individual row of the support structures 146 may be substantially horizontally aligned, in the Y-direction, from horizontal centers of the second contact structures 136B of a horizontally overlapping row of the second contact structures 136B.

The support structures 146 may individually be formed of and include one or more of conductive material, insulative material, and semiconductive material. In some embodiments, the support structures 146 are individually formed of and include conductive material, such as one or more of at least one metal (e.g., W, Ti, Mo, Nb, V, Hf, Ta, Cr, Zr, Fe, Ru, Os, Co, Rh, Ir, Ni, Pa, Pt, Cu, Ag, Au, Al), at least one alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a Mg-based alloy, a Ti-based alloy, a steel, a low-carbon steel, a stainless steel), at least one conductive metal-containing material (e.g., a conductive metal nitride, a conductive metal silicide, a conductive metal carbide, a conductive metal oxide), and at least one conductively-doped semiconductor material (e.g., conductively-doped Si, conductively-doped Ge, conductively-doped SiGe). In additional embodiments, one or more of the support structures 146 are formed of and include one or more of insulative structure and semiconductive material. The support structures 146 may individually be formed of and include a single (e.g., only one) material, or may individually be formed of and including multiple (e.g., more than one) materials. By way of non-limiting example, the support structures 146 may individually be formed to include a conductive core material surrounded by an insulative liner material. The insulative liner material substantially surround (e.g., substantially horizontally and vertically cover) sidewalls of the conductive core material of the support structures 146. The insulative liner material may be horizontally interposed between the conductive core material of the support structures 146 and the tiers 108 (including the conductive material 106 and the insulative material 104 thereof) of the stack structure 102.

Referring collectively to FIGS. 2A through 2D, the microelectronic device structure 100 further includes additional filled slot structures 110 and at least one further filled slot structure 111. The additional filled slot structures 110 horizontally extend in the X-direction and vertically extend in the Z-direction partially (e.g., less than completely) through at least some (e.g., each) of the blocks 134 of the stack structure 102. The further filled slot structure 111 horizontally extends in the Y-direction and vertically extends in the Z-direction partially through at least some (e.g., each) of the blocks 134 of the stack structure 102. The further filled slot structure 111 may be horizontally offset, in the X-direction, from each of the additional filled slot structures 110. As shown in FIG. 2A, the additional filled slot structures 110 partially define and horizontally separate (e.g., in the Y-direction) sub-blocks 144 of individual blocks 134 of the stack structure 102. In addition, as shown in FIG. 2A, the further filled slot structure 111 may segment portions of the bridge regions 124 of individual blocks 134 of the stack structure 102.

Within the horizontal area of an individual block 134 of the stack structure 102, the additional filled slot structures 110 may be formed to horizontally extend in the X-direction into a horizontal area of the first stadium structure 112A of the block 134. The additional filled slot structures 110 may, for example, individually horizontally extend in the X-direction through a crest region 122 of the block 134 horizontally neighboring the first stadium structure 112A and partially into a horizontal area of one of the opposing staircase structures 114 (e.g., the reverse staircase structure 114B) of the first stadium structure 112A. Each of the additional filled slot structures 110 may vertically terminate at or within vertical boundaries of the relatively vertically higher tiers 108A of the stack structure 102. In some embodiments, each of the additional filled slot structures 110 horizontally terminates (e.g., horizontally ends) in the X-direction at or above a relatively lowest step 116 of the one of the opposing staircase structures 114 (e.g., the reverse staircase structure 114B) within vertical boundaries (e.g., in the Z-direction) defined by the relatively vertically higher tiers 108A of the stack structure 102. Within an individual block 134, horizontal ends of the relatively lowest tier 108 of the relatively vertically higher tiers 108A of the stack structure 102 may define the relatively lowest step 116 of the one of the opposing staircase structures 114 (e.g., the reverse staircase structure 114B).

An individual block 134 of the stack structure 102 may include greater than or equal to one (1) of the additional filled slot structures 110 within a horizontal area thereof, such as greater than or equal to two (2) of the additional filled slot structures 110, or greater than or equal to three (3) of the additional filled slot structures 110. In some embodiments, at least some (e.g., each) of the blocks 134 of the stack structure 102 individually includes three (3) of the additional filled slot structures 110 within a horizontal area thereof. For example, as shown in FIGS. 2A and 2C, an individual block 134 may include a first additional filled slot structure 110A, a second additional filled slot structure 110B, and a third additional filled slot structure 110C. The second additional filled slot structure 110B may be horizontally interposed between the first additional filled slot structure 110A and the third additional filled slot structure 110C in the Y-direction. The additional filled slot structures 110 may sub-divide each block 134 into at least two (2) sub-blocks 144. For example, as shown in FIG. 2A, if an individual block 134 includes three (3) of the additional filled slot structures 110 (e.g., the first additional filled slot structure 110A, the second additional filled slot structure 110B, and the third additional filled slot structure 110C) within a horizontal area thereof, the additional filled slot structures 110 may sub-divide the block 134 into four (4) sub-blocks 144, such as a first sub-block 144A, a second sub-block 144B, a third sub-block 144C, and a fourth sub-block 144D.

Referring collectively to FIGS. 2A through 2D, within an individual block 134 of the stack structure 102, the sub-blocks 144 and additional filled slot structures 110 may partially define horizontal boundaries of different upper select gate structures (e.g., drain side select gate (SGD) structures) for upper select transistors (e.g., drain side select transistors) of the block 134. The conductive material 106 of at least some of the vertically higher tiers 108A, as segmented by the additional filled slot structures 110, may form the upper select gate structures. For example, for an individual block 134, an individual vertically higher tier 108A may include four (4) upper select gate structures, wherein each of the upper select gate structures is positioned within a different one of the four (4) sub-blocks 144 (e.g., the first sub-block 144A, the second sub-block 144B, the third sub-block 144C, the fourth sub-block 144D) of the block 134 than each other of the upper select gate structures. The additional filled slot structures 110 within a horizontal area of the block may horizontally intervene between (e.g., in the Y-direction) and separate the upper select gate structures of the individual vertically higher tier 108A. In addition, within an individual block 134 of the stack structure 102, the conductive material 106 of at least some of the relatively vertically lower tiers 108B may be employed to form access line structures (e.g., word line structures) of the block 134. Moreover, within an individual block 134 of the stack structure 102, the conductive material 106 of at least vertically lowest one of the relatively vertically lower tiers 108B may be employed to form as at least one lower select gate structure (e.g., at least one source side select gate (SGS) structure) for lower select transistors (e.g., source side select transistors) of the block 134.

As shown in FIG. 2A, at least some of the additional filled slot structures 110 may be formed and configured to exhibit at least partially non-linear paths extending in the X-direction. For example, for an individual block 134, at least some of the additional filled slot structures 110 may exhibit at least partially non-linear (e.g., weavy) paths including curved (e.g., arcuate) portions within a horizontal area of the first stadium structure 112A. As shown in FIG. 2A, in some embodiments, portions of the first additional filled slot structure 110A and the third additional filled slot structure 110C within a horizontal area of the reverse staircase structure 114B of an individual first stadium structure 112A exhibit non-linear (e.g., weavy) horizontal paths. The non-linear paths of the additional filled slot structures 110 may facilitate desired positions and arrangements of the first contact structures 136A within a horizontal area of the first stadium structure 112A (e.g., within a horizontal area of the reverse staircase structure 114B thereof). For example, the curved portions of an individual additional filled slot structure 110 (e.g., the first additional filled slot structure 110A, the third additional filled slot structure 110C) may divert the additional filled slot structure 110 around the first contact structures 136A of two (2) rows of the first contact structures 136A horizontally neighboring the additional filled slot structure 110 in the Y-direction. The curved portions of the additional filled slot structure 110 may permit the two (2) rows of the first contact structures 136A to be positioned relatively closer to one another in the Y-direction, while still permitting the additional filled slot structure 110 to electrically isolate the first contact structures 136A of the two rows (and the select gate structures in electrical communication with the first contact structures 136A of the two rows) from one another. The non-linear paths of the additional filled slot structures 110 may permit each of the sub-blocks 144 of an individual block 134 to include a group of first contact structures 136A operatively associated therewith, while also facilitating horizontal offset in the X-direction between first contact structures 136A associated with different sub-blocks 144 horizontally neighboring one another in the Y-direction. As also shown in FIG. 2A, at least partially depending on an arrangement of the first contact structures 136A, at least one of the additional filled slot structures 110 (e.g., a central additional filled slot structure 110 in the Y-direction, such as the second additional filled slot structure 110B) may be formed and configured to exhibit a substantially linear path extending in the X-direction.

Referring collectively to FIGS. 2A and 2C, for an individual block 134 of the stack structure 102, at least one of the additional filled slot structures 110 may horizontally overlap, in the Y-direction, at least one row of the support structures 146. The additional filled slot structure 110 may vertically extend (e.g., in the Z-direction) into some of the support structures 146 of the row of the support structures 146. For example, as shown in FIGS. 2A and 2C, for an individual block 134, the second additional filled slot structure 110B may horizontally overlap a central row of the support structures 146 in the Y-direction, and may vertically extend into upper portions of some of the support structures 146 of the central row positioned within a horizontal area of the reverse staircase structure 114B of the first stadium structure 112A. The second additional filled slot structure 110B may segment an upper portion of each of the some of the support structures 146 of the central row into two (2) upper sub-portions separated from one another in the Y-direction by the second additional filled slot structure 110B.

Referring to collectively FIGS. 1, 2A, and 2B, for an individual block 134 of the stack structure 102, the further filled slot structure 111 (FIGS. 2A and 2B) may horizontally overlap the first stadium structure 112A in the X-direction, may horizontally extend in the Y-direction through each of the bridge regions 124 (FIGS. 1 and 2A) horizontally neighboring the first stadium structure 112A in the Y-direction, and may at least partially vertically extend in the Z-direction through each of the bridge regions 124 horizontally neighboring the first stadium structure 112A. The further filled slot structure 111 may vertically extend through and segment (e.g., partition) portions of the conductive material 106 (FIGS. 1 and 2B) of each of the relatively vertically higher tiers 108A (FIG. 2B) of the stack structure 102 within horizontal areas of the bridge regions 124 horizontally neighboring the first stadium structure 112A. The further filled slot structure 111 may segment first portions of the conductive material 106 of each of the relatively vertically higher tiers 108A within the first bridge region 124A (FIGS. 1 and 2A) horizontally neighboring a first side of the first stadium structure 112A; and may also segment second portions of the conductive material 106 of each of the relatively vertically higher tiers 108A within the second bridge region 124B (FIGS. 1 and 2A) horizontally neighboring a second, opposing side of the first stadium structure 112A. In some embodiments, the further filled slot structure 111 horizontally overlaps the central region 118 of the first stadium structure 112A in the X-direction. The further filled slot structure 140 disrupts (e.g., breaks, destroys) at least some conductive paths extending from and between two (2) of the crest regions 122 horizontally neighboring (e.g., in the X-direction) the first stadium structure 112A by way of the bridge regions 124 horizontally neighboring (e.g., in the Y-direction) the first stadium structure 112A. The further filled slot structure 111 may prevent shorting of first upper select gate structures of the first sub-block 144A (FIG. 2A) of the block 134 with fourth upper select gate structures of the fourth sub-block 144D (FIG. 2A) of the block 134. Namely, the further filled slot structure 111 may destroy conductive paths extending across the bridge regions 124 horizontally neighboring the first stadium structure 112A that may otherwise short the first upper select gate structures of the first sub-block 144A to the fourth upper select gate structures of the fourth sub-block 144D by way of third portions of the conductive material 106 of each of the relatively vertically higher tiers 108A within one of the crest regions 122 (e.g., a crest region 122 free of the additional filled slot structures 110 (FIG. 2A)) horizontally neighboring the first stadium structure 112A.

The additional filled slot structures 110 and the further filled slot structure 111 may comprise slots (e.g., openings, trenches, slits) in the stack structure 102 filled with at least one dielectric material. A material composition of the dielectric material of the additional filled slot structures 110 and the further filled slot structure 111 may be substantially the same as a material composition of the dielectric material of the filled slot structures 140; or the material composition of the dielectric material of the additional filled slot structures 110 and/or the further filled slot structure 111 may be different than the material composition of the dielectric material of the filled slot structures 140. In some embodiments, the additional filled slot structures 110 and the further filled slot structure 111 are individually formed of and include at least one dielectric oxide material (e.g., SiOₓ, such as SiO₂).

Referring collectively to FIGS. 2A through 2D, the microelectronic device structure 100 further includes select line routing structures 148 in electrical communication with the first contact structures 136A and deep contact structures 138 vertically extending through the stack structure 102. The select line routing structures 148 may vertically overly an upper boundary of the stack structure 102. Within a horizontal area of an individual block 134, select line routing structures 148 may individually horizontally extend from a deep contact structure 138 horizontally positioned within a crest region 122 of the block 134 at least to one or more (e.g., each of a group, each of a row) of the first contact structures 136A within a horizontal area of the first stadium structure 112A of the block 134. In addition, as shown in FIG. 2A, portions of the select line routing structures 148 may be employed as jumper structures extending over the further filled slot structure 111 to facilitate electrical communication between first contact structures 136A horizontally separated from one another by the further filled slot structure 111. For example, a portion of an individual select line routing structure 148 may horizontally extend in the X-direction from one or more of the first contact structures 136A positioned within a horizontal area of the reverse staircase structure 114B of the first stadium structure 112A to at least one (e.g., only one) other of the first contact structures 136A positioned within a horizontal area of the reverse staircase structure 114B of the first stadium structure 112A. In some embodiments, at least some (e.g., each) of the select line routing structures 148 extend in substantially linear paths in the X-direction.

As shown in FIG. 2A, select line routing structures 148 may individually be sized, shaped and configured to electrically connect (e.g., gang) multiple first contact structures 136A positioned within the same sub-block 144 (e.g., the first sub-block 144A, the second sub-block 144B, the third sub-block 144C, the fourth sub-block 144D) as one another to one another. As a non-limiting example, an individual select line routing structure 148 may be electrically connected to at least some (e.g., all) of the first contact structures 136A of a first row of the first contact structures 136A positioned within horizontal boundaries in the Y-direction of the first sub-block 144A of an individual block 134 of the stack structure 102. As another non-limiting example, another individual select line routing structure 148 may be electrically connected to at least some (e.g., all) of the first contact structures 136A of a second row of the first contact structures 136A positioned within horizontal boundaries in the Y-direction of the second sub-block 144B of the individual block 134 of the stack structure 102. As an additional non-limiting example, yet another individual select line routing structure 148 may be electrically connected to at least some (e.g., all) of the first contact structures 136A of a third row of the first contact structures 136A positioned within horizontal boundaries in the Y-direction of the third sub-block 144C of the individual block 134 of the stack structure 102. As a further non-limiting example, yet still another individual select line routing structure 148 may be electrically connected to at least some (e.g., all) of the first contact structures 136A of a fourth row of the first contact structures 136A positioned within horizontal boundaries in the Y-direction of the fourth sub-block 144D of the individual block 134 of the stack structure 102.

The select line routing structures 148 may be formed of and include conductive material. As a non-limiting example, the select line routing structures 148 may be formed of and include one or more of at least one metal, at least one alloy, and at least one conductive metal-containing material (e.g., a conductive metal nitride, a conductive metal silicide, a conductive metal carbide, a conductive metal oxide). A material composition of the select line routing structures 148 may be substantially the same as a material composition of the conductive material 106 of the tiers 108 of the stack structure 102, or the material composition of select line routing structures 148 may be different than the material composition of the conductive material 106 of the tiers 108 of the stack structure 102. In some embodiments, the select line routing structures 148 are individually formed of and include W. The select line routing structures 148 may individually be homogeneous, or the select line routing structures 148 may individually be heterogeneous.

In additional embodiments, the microelectronic device structure 100 may be formed to have a different configuration than that previously described with reference to FIGS. 1 and 2A through 2D. The microelectronic device structure 100 may, for example, be formed to exhibit a configuration such as one of the configurations depicted in FIGS. 3 through 5 and described in further detail below. With the description provided below, it will be readily apparent to one of ordinary skill in the art that the structures and devices described herein may be included in relatively larger structures, devices, and systems.

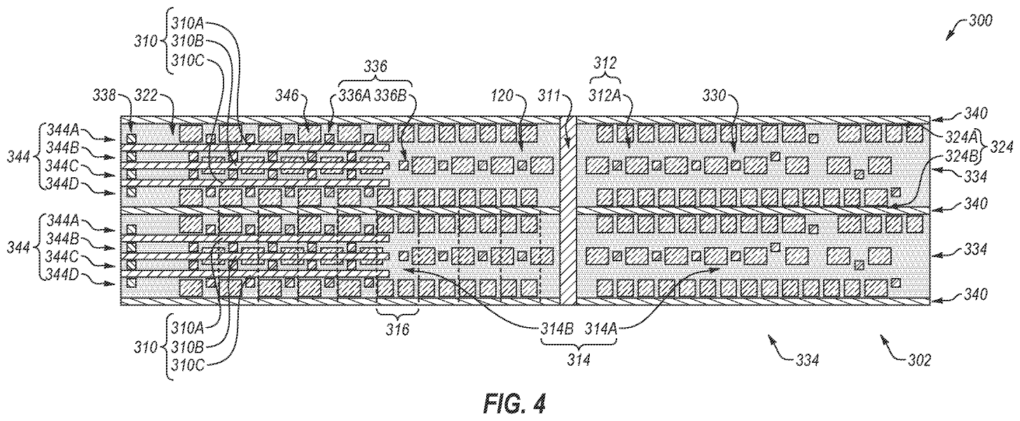

Before referring to FIG. 3, it will be understood that throughout the FIGS. 3 through 6 and the associated description, features (e.g., regions, materials, structures, devices) functionally similar to previously described features (e.g., previously described materials, structures, devices) are referred to with similar reference numerals incremented by 100. To avoid repetition, not all features shown in FIGS. 3 through 6 are described in detail herein. Rather, unless described otherwise below, a feature in one or more of FIGS. 3 through 6 designated by a reference numeral that is a 100 increment of the reference numeral of a feature previously described with reference to one or more of FIGS. 1 and 2A through 2D will be understood to be substantially similar to and have substantially the same advantages as the previously described feature. In addition, unless described otherwise below, a feature in one or more of FIGS. 4 through 6 designated by a reference numeral that is a 100 increment of the reference numeral of a feature previously described with reference to a preceding one or more of FIGS. 3 through 5 will be understood to be substantially similar to and have substantially the same advantages as the previously described feature. As a non-limiting example, unless described otherwise below, features designated by the reference numerals 236, 336, 436, and 536 in FIGS. 3 through 6, respectively, will be understood to respectively be substantially similar to and have substantially the same advantages as the contact structures 136 previously described herein with reference to FIGS. 2A through 2D. In addition, for clarity and ease of understanding the drawings and related description, some features (e.g., structures, materials, regions, devices) previously described with reference to one or more of FIGS. 1 and 2A through 2D are not depicted in FIGS. 3 through 6. However, unless described otherwise below, it will be under that any features of the microelectronic device structure 100 previously described with reference to FIGS. 1 and 2A through 2D may be included in any of the different configurations described hereinbelow with reference to FIGS. 3 through 6. As a non-limiting example, features substantially similar to the select line routing structures 148 previously described with reference to FIGS. 2A through 2D may be included in the different configurations described hereinbelow with reference to FIGS. 3 through 6.

FIG. 3 is a simplified, partial top-down view of a microelectronic device structure 200, in accordance with additional embodiments of the disclosure. The microelectronic device structure 200 may be similar to the microelectronic device structure 100 previously described with reference to FIGS. 1 and 2A through 2D, except that, for example, the microelectronic device structure 200 may exhibit a different arrangement of the first contact structures 236A and some of the support structures 246 thereof, as well as different configurations of some of the additional filled slot structures 210 thereof.

As shown in FIG. 3, similar to the configuration of the microelectronic device structure 100 previously described with reference to FIG. 2A, an individual group of the first contact structures 236A positioned along (e.g., with a horizontal area of, horizontally overlapping) an individual step 216 of the first stadium structure 212A (e.g., of the reverse staircase structure 214B thereof) may include four (4) of the first contact structures 236A. An outermost two (2) of the four (4) of the first contact structures 236A of the group in the Y-direction may be substantially aligned with one another in the X-direction; and an innermost two (2) of the four (4) of the first contact structures 136A of the group in the Y-direction may be substantially aligned with one another in the X-direction and offset in the X-direction from the outermost two (2) of the four (4) of the first contact structures 136A. However, unlike the configuration of the microelectronic device structure 100 previously described with reference to FIG. 2A, the outermost two (2) of the four (4) of the first contact structures 236A may individually be horizontally positioned relatively closer, in the X-direction, to a vertically lower step 216 of the first stadium structure 212A (e.g., of the reverse staircase structure 214B thereof) than the innermost two (2) of the four (4) of the first contact structures 236A. Put another way, the innermost two (2) of the four (4) of the first contact structures 236A may individually be horizontally positioned relatively closer, in the X-direction, to a vertically higher step 216 of the first stadium structure 212A (e.g., of the reverse staircase structure 214B thereof) than the outermost two (2) of the four (4) of the first contact structures 236A.

As also shown in FIG. 3, the modified arrangement of the first contact structures 236A of the microelectronic device structure 200 relative to the arrangement of the first contact structures 136A (FIGS. 2A through 2D) of the microelectronic device structure 100 (FIGS. 2A through 2D) effectuates a modified arrangement of the support structures 246 horizontally alternating in the X-direction with the first contact structures 236A relative to the arrangement of the support structures 146 (FIGS. 2A through 2D) of the microelectronic device structure 100 (FIGS. 2A through 2D). An individual group of the support structures 246 horizontally overlapping an individual step 216 of the first stadium structure 212A (e.g., of the reverse staircase structure 214B thereof) may include three (3) of the support structures 246. An outermost two (2) of the three (3) of the support structures 246 of the group in the Y-direction may be substantially aligned with one another in the X-direction; and an innermost one (1) of the three (3) of the support structures 246 of the group in the Y-direction may be offset in the X-direction from the outermost two (2) of the three (3) of the support structures 246. The outermost two (2) of the three (3) of the support structures 246 may individually be horizontally positioned relatively closer, in the X-direction, to a vertically higher step 216 of the first stadium structure 212A (e.g., of the reverse staircase structure 214B thereof) than the innermost one (1) of the three (3) of the support structures 246. Put another way, the innermost one (1) of the three (3) of the support structures 246 may be horizontally positioned relatively closer, in the X-direction, to a vertically lower step 216 of the first stadium structure 212A (e.g., of the reverse staircase structure 214B thereof) than the outermost two (2) of the three (3) of the support structures 246.

At least partially due to the arrangements of the first contact structures 236A and the support structures 246, at least the first additional filled slot structure 210A and the third additional filled slot structure 210C may exhibit different non-linear horizontal paths than the first additional filled slot structure 110A (FIG. 2A) and the third additional filled slot structure 110C (FIG. 2A) of the microelectronic device structure 100 (FIG. 2A). For example, the positions in the X-direction of the curved portions of the first additional filled slot structure 210A and the third additional filled slot structure 210C may be shifted in the X-direction relative to similarly curved portions of the first additional filled slot structure 110A (FIG. 2A) and the third additional filled slot structure 110C (FIG. 2A) of the microelectronic device structure 100 (FIG. 2A).

FIG. 4 is a simplified, partial top-down view of a microelectronic device structure 300, in accordance with further embodiments of the disclosure. The microelectronic device structure 300 may be similar to the microelectronic device structure 200 previously described with reference to FIG. 3, except that, for example, the microelectronic device structure 300 may exhibit different configurations of some of the additional filled slot structures 310 thereof. For example, each of the additional filled slot structures 310 (e.g., each of the first filled slot structure 310A, the second filled slot structure 310B, and the third filled slot structure 310C) within a horizontal area of an individual block 334 of the stack structure 302 may horizontally extend in a substantially linear path in the X-direction.

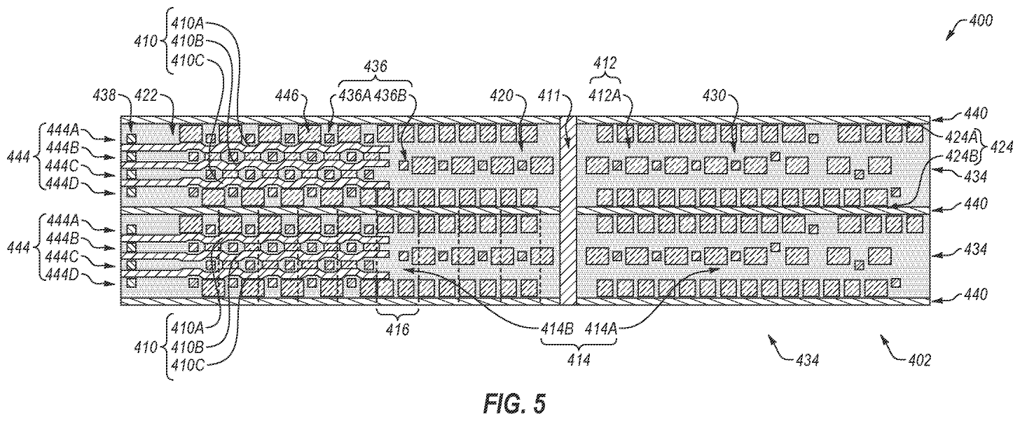

FIG. 5 is a simplified, partial top-down view of a microelectronic device structure 400, in accordance with yet further embodiments of the disclosure. The microelectronic device structure 400 may be similar to the microelectronic device structure 200 previously described with reference to FIG. 3, except that, for example, the microelectronic device structure 400 may exhibit a different arrangement of the first contact structures 436A and some of the support structures 446 thereof, as well as different configurations of some of the additional filled slot structures 410 thereof.

As shown in FIG. 5, similar to the configuration of the microelectronic device structure 200 previously described with reference to FIG. 3, an individual group of the first contact structures 436A positioned along (e.g., with a horizontal area of, horizontally overlapping) an individual step 416 of the first stadium structure 412A (e.g., of the reverse staircase structure 414B thereof) may include four (4) of the first contact structures 436A. However, unlike the configuration of the microelectronic device structure 200 previously described with reference to FIG. 3, every other one of the first contact structures 436A in the Y-direction may be horizontally aligned with another in the X-direction, and may be horizontally offset in the X-direction from at least one other of the first contact structures 436A most proximate thereto in the Y-direction. Odd first contact structures 436A in the Y-direction of the four (4) of the first contact structures 436A may individually be horizontally positioned relatively closer, in the X-direction, to a vertically lower step 416 of the first stadium structure 412A (e.g., of the reverse staircase structure 414B thereof) than even first contact structures 436A in the Y-direction of the four (4) of the first contact structures 436A. In additional embodiments, even first contact structures 436A in the Y-direction of the four (4) of the first contact structures 436A may individually be horizontally positioned relatively closer, in the X-direction, to a vertically lower step 416 of the first stadium structure 412A (e.g., of the reverse staircase structure 414B thereof) than odd first contact structures 436A in the Y-direction of the four (4) of the first contact structures 436A.

As also shown in FIG. 5, the modified arrangement of the first contact structures 436A of the microelectronic device structure 400 relative to the arrangement of the first contact structures 236A (FIG. 3) of the microelectronic device structure 200 (FIG. 3) effectuates a modified arrangement and/or modified geometric configurations (e.g., sizes, shapes) of at least some of the support structures 446 horizontally alternating in the X-direction with the first contact structures 436A relative to the arrangement and/or the geometric configurations (e.g., sizes, shapes) of the support structures 246 (FIG. 3) of the microelectronic device structure 200 (FIG. 3). An individual group of the support structures 446 horizontally overlapping an individual step 416 of the first stadium structure 412A (e.g., of the reverse staircase structure 414B thereof) may include three (3) of the support structures 446. An outermost two (2) of the three (3) of the support structures 446 of the group in the Y-direction may be offset from one another in the X-direction. In addition, an innermost one (1) of the three (3) of the support structures 446 of the group in the Y-direction may be substantially aligned in the X-direction with one of the outermost two (2) of the three (3) of the support structures 446, and may be offset in the X-direction from the other of the outermost two (2) of the three (3) of the support structures 446. The innermost one (1) of the innermost one (1) of the three (3) of the support structures 446 of the group may also have a relatively smaller horizontal areas than each of the outermost two (2) of the three (3) of the support structures 446. One of the outermost two (2) of the three (3) of the support structures 446 may be horizontally positioned relatively closer, in the X-direction, to a vertically higher step 416 of the first stadium structure 412A (e.g., of the reverse staircase structure 214B thereof) than the other of the outermost two (2) of the three (3) of the support structures 446.

At least partially due to the arrangements of the first contact structures 436A and the support structures 446, some of the additional filled slot structures 410 (e.g., the second additional filled slot structure 410B, the third additional filled slot structure 410C) may exhibit different horizontal paths than corresponding additional filled slot structures 210 (e.g., the second additional filled slot structure 210B (FIG. 3), the third additional filled slot structure 210C (FIG. 3)) of the microelectronic device structure 200 (FIG. 3). For example, the second additional filled slot structure 410B may extend in a substantially linear path in the X-direction. As another example, the positions in the X-direction of the curved portions of the third additional filled slot structure 410C may be shifted in the X-direction relative to similarly curved portions of the third additional filled slot structure 210C (FIG. 3) of the microelectronic device structure 200 (FIG. 3).

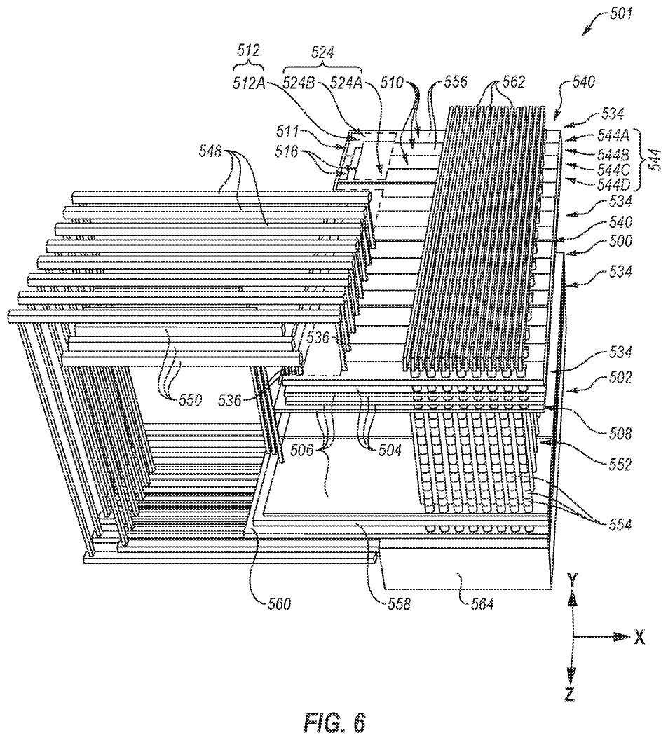

Microelectronic device structures (e.g., the microelectronic device structures 100, 200, 300, 400 previously descried with reference to one or more of FIGS. 1 through 5) of the disclosure may be included in microelectronic devices of the disclosure. For example, FIG. 6 illustrates a partial cutaway perspective view of a portion of a microelectronic device 501 (e.g., a memory device, such as a 3D NAND Flash memory device) including a microelectronic device structure 500. The microelectronic device structure 500 may be substantially similar to one of the microelectronic device structure 100 (FIGS. 1 and 2A through 2D), the microelectronic device structure 200 (FIG. 3), the microelectronic device structure 300 (FIG. 4), and the microelectronic device structure 400 (FIG. 5).

As shown in FIG. 6, in addition to the features of the microelectronic device structure 500 previously described herein in relation to one or more of the microelectronic device structure 100 (FIGS. 1 and 2A through 2D), 200 (FIG. 3), 300 (FIG. 4), 400 (FIG. 5), the microelectronic device 501 may further include cell pillar structures 552 vertically extending through at least some of the blocks 534 of the stack structure 502. The cell pillar structures 552 may be positioned within regions (e.g., memory array regions) of the blocks 534 horizontally offset (e.g., in the X-direction) from the stadium structures 512 (e.g., the first stadium structure 512A) (and, hence, the bridge regions 526) of the blocks 534. Intersections of the cell pillar structures 552 and the conductive material 506 of the tiers 508 of the stack structure 502 within the horizontal areas of the blocks 534 form strings of memory cells 554 vertically extending through the blocks 534 of the stack structure 502. For each string of memory cells 554, the memory cells 554 thereof may be coupled in series with one another. Within an individual block 534, the conductive material 506 of some of the tiers 508 of the stack structure 502 may serve as access line structures (e.g., word line structures) for the strings of memory cells 554 within the horizontal area of the block 534. In some embodiments, within an individual block 534, the memory cells 554 formed at the intersections of the conductive material 506 of some of the tiers 508 and the cell pillar structures 552 comprise so-called “MONOS” (metal-oxide-nitride-oxide-semiconductor) memory cells. In additional embodiments, the memory cells 554 comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, the memory cells 554 comprise so-called “floating gate” memory cells including floating gates (e.g., metallic floating gates) as charge storage structures. The floating gates may horizontally intervene between central structures of the cell pillar structures 552 and the conductive material 506 of the different tiers 508 of the stack structure 502.

The microelectronic device 501 may further include at least one source structure 560, access line routing structures 550, first select gates 556 (e.g., upper select gates, drain select gates (SGDs)), select line routing structures 548, one or more second select gates 558 (e.g., lower select gates, source select gate (SGSs)), and digit line structures 562. The digit line structures 562 may vertically overlie and be coupled to the cell pillar structures 552 (and, hence, the strings of memory cells 554). The source structure 560 may vertically underlie and be coupled to the cell pillar structures 552 (and, hence, the strings of memory cells 554). In addition, the contact structures 536 may couple various features of the microelectronic device 501 to one another as shown (e.g., the select line routing structures 548 to the first select gates 556; the access line routing structures 550 to the conductive material 506 of the tiers 508 of the stack structure 502 underlying the first select gates 556 and defining access line structures of the microelectronic device 501).

The microelectronic device 501 may also include a base structure 564 positioned vertically below the cell pillar structures 552 (and, hence, the strings of memory cells 554). The base structure 564 may include at least one control logic region including control logic devices configured to control various operations of other features (e.g., the strings of memory cells 554) of the microelectronic device 501. As a non-limiting example, the control logic region of the base structure 564 may further include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. The control logic region of the base structure 564 may be coupled to the source structure 560, the access line routing structures 550, the select line routing structures 548, and the digit line structures 562. In some embodiments, the control logic region of the base structure 564 includes CMOS (complementary metal-oxide-semiconductor) circuitry. In such embodiments, the control logic region of the base structure 564 may be characterized as having a “CMOS under Array” (“CuA”) configuration.

Thus, in accordance with embodiments of the disclosure, a microelectronic device comprises a stack structure and conductive contact structures. The stack structure comprises tiers each including conductive material vertically neighboring insulative material. The stack structure is divided into blocks horizontally extending in parallel in a first direction and separated from one another in a second direction orthogonal to the first direction by insulative slot structures. At least one of the blocks comprises a lower stadium structure and an upper stadium structure. The lower stadium structure has steps comprising edges of some of the tiers. The upper stadium structure vertically overlies the lower stadium structure and has additional steps comprising edges of some other of the tiers vertically overlying the some of the tiers. The additional steps have greater tread widths in the first direction than the steps. The conductive contact structures are in contact with at least some of the additional steps of the upper stadium structure of the at least one of the blocks.

Furthermore, in accordance with embodiments of the disclosure, a memory device comprises a stack structure, groups of contact structures, and strings of memory cells. The stack structure comprises blocks separated from one another by dielectric slot structures and each including a vertically alternating sequence of conductive structures and insulative structures arranged in tiers. At least one of the blocks comprises stadium structures, crest regions, and bridge regions. The stadium structures comprise an upper stadium structure and lower stadium structures. The upper stadium structure comprises staircase structures having steps comprising edges of an upper group of the tiers of the stack structure. The lower stadium structures are vertically below the upper stadium structure and each comprises additional staircase structures having additional steps comprising edges of a lower group of the tiers of the stack structure. The additional steps have smaller tread dimensions in a first direction than the steps. The crest regions are interposed between the stadium structures in the first direction. The bridge regions are integral with the crest regions and are interposed between the dielectric slot structures and the stadium structures in a second direction orthogonal to the first direction. The groups of contact structures are in contact with and are substantially confined within horizontal areas of the steps of the upper stadium structure of the at least one of the blocks. Each of the groups of contact structures individually comprises two of the contact structures substantially aligned with one another in the first direction, and two other of the contact structures substantially aligned with one another in the first direction and offset from the two of the contact structures in the first direction. The strings of memory cells vertically extend through a portion of the at least one of the blocks neighboring the upper stadium structure in the first direction.

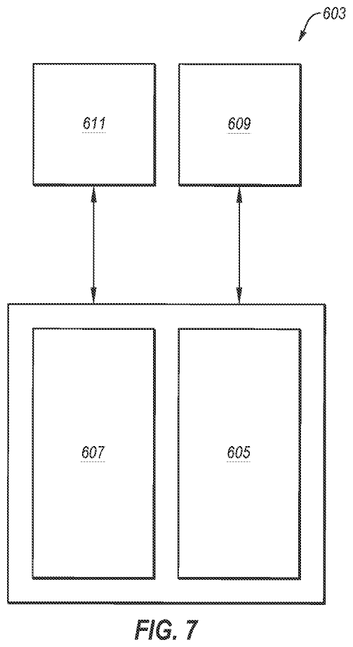

Microelectronic devices structures (e.g., the microelectronic device structures 100, 200, 300, 400 previously described with reference to one or more of FIGS. 1 through 5) and microelectronic devices (e.g., the microelectronic device 501 previously described with reference to FIG. 6) in accordance with embodiments of the disclosure may be used in embodiments of electronic systems of the disclosure. For example, FIG. 7 is a block diagram of an illustrative electronic system 603 according to embodiments of disclosure. The electronic system 603 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® tablet, a SURFACE® tablet, an electronic book, a navigation device. The electronic system 603 includes at least one memory device 605. The memory device 605 may comprise, for example, one or more of a microelectronic device structure (e.g., the microelectronic device structures 100, 200, 300, 400 previously described with reference to one or more of FIGS. 1 through 5) and a microelectronic device (e.g., the microelectronic device 501 previously described with reference to FIG. 6) previously described herein. The electronic system 603 may further include at least one electronic signal processor device 607 (often referred to as a “microprocessor”). The electronic signal processor device 607 may, optionally, include one or more of a microelectronic device structure (e.g., the microelectronic device structures 100, 200, 300, 400 previously described with reference to one or more of FIGS. 1 through 5) and a microelectronic device (e.g., the microelectronic device 501 previously described with reference to FIG. 6) previously described herein. While the memory device 605 and the electronic signal processor device 607 are depicted as two (2) separate devices in FIG. 7, in additional embodiments, a single (e.g., only one) memory/processor device having the functionalities of the memory device 605 and the electronic signal processor device 607 may be included in the electronic system 603. In such embodiments, the memory/processor device may include one or more of a microelectronic device structure (e.g., the microelectronic device structures 100, 200, 300, 400 previously described with reference to one or more of FIGS. 1 through 5) and a microelectronic device (e.g., the microelectronic device 501 previously described with reference to FIG. 6) previously described herein. The electronic system 603 may further include one or more input devices 609 for inputting information into the electronic system 603 by a user, such as, for example, a mouse or other pointing device, a keyboard, a touchpad, a button, or a control panel. The electronic system 603 may further include one or more output devices 611 for outputting information (e.g., visual or audio output) to a user such as, for example, a monitor, a display, a printer, an audio output jack, a speaker, etc. In some embodiments, the input device 609 and the output device 611 comprise a single touchscreen device that can be used both to input information to the electronic system 603 and to output visual information to a user. The input device 609 and the output device 611 may communicate electrically with one or more of the memory device 605 and the electronic signal processor device 607.

Thus, in accordance with embodiments of the disclosure, an electronic system comprises an input device, an output device, a processor device operably coupled to the input device and the output device, and a memory device operably coupled to the processor device. The memory device comprises a stack structure having tiers each including conductive material vertically neighboring insulative material. The stack structure is divided into blocks separated from one another by dielectric slot structures. At least one of the blocks comprises a lower stadium structure having steps comprising edges of a vertically lower group of the tiers, and an uppermost stadium structure having additional steps comprising edges of a vertically upper group of the tiers. The additional steps have greater horizontal dimensions than the steps. The memory device further comprises contact structures, additional dielectric slot structures, and strings of memory cells. The contact structures are in contact with the additional steps of the uppermost stadium structure of the at least one of the blocks. A group of the contact structures is substantially confined within a horizontal area of the one of the additional steps and comprises at least one contact structure diagonally horizontally positioned relative to at least one other contact structure. The additional dielectric slot structures vertically extend through the vertically upper group of the tiers of the at least one of the blocks and partially horizontally overlap the uppermost stadium structure. The additional dielectric slot structures horizontally alternate with rows of the contact structures. The strings of memory cells vertically extend through the at least one of the blocks.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other embodiments of the disclosure.

What is claimed is:

1. A microelectronic device, comprising:
a stack structure comprising tiers each including conductive material vertically neighbouring insulative material, the stack structure divided into blocks horizontally extending in parallel in a first direction and separated from one another in a second direction orthogonal to the first direction by insulative slot structures, at least one of the blocks comprising:
a lower stadium structure having steps comprising edges of some of the tiers;
an upper stadium structure vertically overlying the lower stadium structure and having additional steps comprising edges of some other of the tiers vertically overlying the some of the tiers, the additional steps having greater tread widths in the first direction than the steps; and
conductive contact structures in contact with at least some of the additional steps of the upper stadium structure of the at least one of the blocks.

2. The microelectronic device of claim 1, wherein at least some of the additional steps of the upper stadium structure individually have a group of the conductive contact structures within a horizontal area thereof.

3. The microelectronic device of claim 2, wherein the group of the conductive contact structures within the horizontal area of one additional step of the at least some of the additional steps comprise at least three of the conductive contact structures, at least one of the at least three of the conductive contact structures offset in the first direction from at least one other of the at least three of the conductive contact structures.

4. The microelectronic device of claim 2, wherein the group of the conductive contact structures within the horizontal area of one additional step of the at least some of the additional steps comprises:
two of the conductive contact structures substantially aligned with one another in the first direction; and
two other of the conductive contact structures substantially aligned with one another in the first direction and offset from the two of the conductive contact structures in the first direction.

5. The microelectronic device of claim 4, wherein both of the two of the conductive contact structures are interposed in the second direction between the two other of the conductive contact structures.

6. The microelectronic device of claim 5, wherein the two of the conductive contact structures are located relatively closer, in the first direction, to a vertically lower additional step of the at least some of the additional steps than the two other of the conductive contact structures.

7. The microelectronic device of claim 5, wherein the two of the conductive contact structures are located relatively closer, in the first direction, to a vertically higher additional step of the at least some of the additional steps than the two other of the conductive contact structures.

8. The microelectronic device of claim 4, wherein only one of the two of the conductive contact structures is interposed in the second direction between the two other of the conductive contact structures.

9. The microelectronic device of claim 2, wherein at least some other of the additional steps of the upper stadium structure individually have only one of the conductive contact structures within a horizontal area thereof.

10. The microelectronic device of claim 2, further comprising additional insulative slot structures partially vertically extending through the at least one of the blocks and individually horizontally extending partially through the upper stadium structure in the first direction, the additional insulative slot structures individually interposed in the second direction between neighboring conductive contact structures of the group of the conductive contact structures.

11. The microelectronic device of claim 10, wherein the additional insulative slot structures comprise at least three of the additional insulative slot structures.

12. The microelectronic device of claim 10, wherein a path in the first direction of at least one of the additional insulative slot structures in at least partially non-linear.

13. The microelectronic device of claim 12, wherein the at least one of the additional insulative slot structures horizontally weaves between a row of the conductive contact structures and an additional row of the conductive contact structures horizontally neighboring the row of the conductive contact structures in the second direction, the conductive contact structures of the row of the conductive contact structures horizontally offset in the first direction from the conductive contact structures of the additional row of the conductive contact structures.

14. The microelectronic device of claim 10, wherein a path in the first direction of at least one of the additional insulative slot structures is substantially linear.

15. The microelectronic device of claim 10, further comprising an other insulative slot structure partially vertically extending through the at least one of the blocks and horizontally extending completely across the at least one of the blocks in the second direction, a portion of the other insulative slot structure located with a horizontal area of the upper stadium structure.

16. The microelectronic device of claim 1, further comprising additional contact structures vertically extending completely through the at least one of the blocks, some of the additional contact structures positioned within a horizontal area of the upper stadium structure and horizontally offset from the conductive contact structures.

17. A memory device, comprising:
a stack structure comprising blocks separated from one another by dielectric slot structures and each including a vertically alternating sequence of conductive structures and insulative structures arranged in tiers, at least one of the blocks comprising:
stadium structures comprising:
an upper stadium structure comprising staircase structures having steps comprising edges of an upper group of the tiers of the stack structure; and
lower stadium structures vertically below the upper stadium structure and each comprising additional staircase structures having additional steps comprising edges of a lower group of the tiers of the stack structure, the additional steps having smaller tread dimensions in a first direction than the steps;
crest regions interposed between the stadium structures in the first direction; and
bridge regions integral with the crest regions and interposed between the dielectric slot structures and the stadium structures in a second direction orthogonal to the first direction;
groups of contact structures in contact with and substantially confined within horizontal areas of the steps of the upper stadium structure of the at least one of the blocks, each of the groups of contact structures individually comprising:
two of the contact structures substantially aligned with one another in the first direction; and
two other of the contact structures substantially aligned with one another in the first direction and offset from the two of the contact structures in the first direction; and
strings of memory cells vertically extending through a portion of the at least one of the blocks neighboring the upper stadium structure in the first direction.

18. The memory device of claim 17, wherein each of the steps of the upper stadium structure has a tread width in the first direction within a range of from about 1200 nm to about 1800 nm.

19. The memory device of claim 17, further comprising:
three additional dielectric slot structures vertically extending through the upper group of the tiers of the at least one of the blocks and horizontally extending in the first direction partially through one of the staircase structures of the upper stadium structure; and
a further dielectric slot structure vertically extending through the upper group of the tiers of the at least one of the blocks and horizontally extending in the second direction completely across the at least one of the blocks, the further dielectric slot structure horizontally overlapping the upper stadium structure and horizontally offset from each of the three additional dielectric slot structures in the first direction.

20. The memory device of claim 19, wherein two of the three additional dielectric slot structures horizontally extend in non-linear paths through a horizontal area of the one of the staircase structures of the upper stadium structure.

21. The memory device of claim 20, wherein one of the three additional dielectric slot structures interposed, in the second direction, between the two of the three additional dielectric slot structures horizontally extend in a substantially linear path through the horizontal area of the one of the staircase structures of the upper stadium structure.

22. The memory device of claim 19, further comprising additional contact structures vertically extending completely through the at least one of the blocks and positioned within a horizontal area of the one of the staircase structures of the upper stadium structure.

23. The memory device of claim 22, wherein one of the three additional dielectric slot structures horizontally overlaps a row of the additional contact structures extending in the first direction, the one of the three additional dielectric slot structures partially vertically extending through and in physical contact with some of the additional contact structures of the row of the additional contact structures.

24. An electronic system, comprising:
an input device;
an output device;
a processor device operably coupled to the input device and the output device; and
a memory device operably coupled to the processor device and comprising:
a stack structure having tiers each including conductive material vertically neighbouring insulative material, the stack structure divided into blocks separated from one another by dielectric slot structures, at least one of the blocks comprising:
a lower stadium structure having steps comprising edges of a vertically lower group of the tiers; and
an uppermost stadium structure having additional steps comprising edges of a vertically upper group of the tiers, the additional steps having greater horizontal dimensions than the steps;
contact structures in contact with the additional steps of the uppermost stadium structure of the at least one of the blocks, a group of the contact structures substantially confined within a horizontal area of the one of the additional steps and comprising at least one contact structure diagonally horizontally positioned relative to at least one other contact structure;
additional dielectric slot structures vertically extending through the vertically upper group of the tiers of the at least one of the blocks and partially horizontally overlapping the uppermost stadium structure, the additional dielectric slot structures horizontally alternating with rows of the contact structures; and
strings of memory cells vertically extending through the at least one of the blocks.

25. The electronic system of claim 24, wherein at least some of the additional dielectric slot structures horizontally extend in non-linear paths through a portion of a horizontal area of the uppermost stadium structure of the at least one of the blocks.

26. The electronic system of claim 24, wherein some of the contact structures within at least one of the rows of the contact structures are electrically ganged together by way of conductive routing structures vertically overlying the at least one of the blocks.

27. The electronic system of claim 24, wherein the memory device comprises a 3D NAND Flash memory device.
